(19) United States
(12) Patent Application Publication
(10) Pub. No.: US 2009/0014739 A1
(43) Pub. Date: Jan. 15, 2009

(54) LIGHT-EMITTING DIODE PACKAGE STRUCTURE

(75) Inventors: Jen-Ta Chiang, Tu Chen City (TW); Yi-Tsuo Wu, Jhonghe City (TW); Chia-Hsien Chang, Yongjing Township (TW); Hsiao-Chiao Li, Sinjhuant City (TW)

Correspondence Address: Muncy, Geissler, Olds & Lowe, PLLC, P.O. BOX 1364, FAIRFAX, VA, 22038-1364, US

(73) Assignee: EVERLIGHT ELECTRONICS CO., LTD.

(21) Appl. No.: 12/114,459

(22) Filed: May 2, 2008

(30) Foreign Application Priority Data
Jul. 9, 2007 (TW) 96211149

(51) Int. Cl. H01L 23/00

(52) U.S. Cl. 257/98; 257/99; 257/E23.002

(57) ABSTRACT

The present invention is an improved Light-Emitting Diode (LED) package structure comprising a light-emitting diode chip, a package board of heat conductive semiconductor material, a lead frame, and a circuit. Whereon the package board installs plural thermal vias to conduct the electricity circuit and transmit the heat out of the package due to the LED luminescing as well.

### RELATED APPLICATIONS

This application claims priority to Taiwan Application Serial Number 96211149, filed Jul. 9, 2007, which is herein incorporated by reference.

### BACKGROUND

1. Field of Invention

The present invention relates to an improved Light-Emitting Diode (LED) package structure. More particularly, the present invention relates to a light-emitting diodes package structure of a package substrate with plural thermal vias.

2. Description of Related Art

Light-Emitting Diodes (LED), are widely used in electronic devices or on lamp illumination. Generally, the package substrate of a high power LED is applied as a ceramic substrate. Though, the technique of the manufacture of the ceramic substrate is high, the fragile characteristic and great expense restricts the LED package design. Due to the advantage of low expense of silicon wafer, the manufacturing technology has reached maturity for designing structures in the wafer, and the thermal conductivity of silicon is also close to the ceramic material, though the manufacturing cost of silicon substrate is lower than the manufacturing cost of ceramic substrate, it is possible to save costs for applying a silicon substrate without any adverse effects of the thermal conduction reduction.

As in the LED structure of the surface attaching type in prior art, the installed section of the LED chip is defined by the package base of an aperture rendering the light radiate. During the LED chip operation, some light beaming toward the base sidewall is absorbed or lost through reflecting or scattering, and there is only a small amount of light that can project out through the aperture. Thus the output efficiency is reduced for the absorption of the light causing the power loss. And the accompanying heat accumulation of the LED operation is another disadvantage against the luminous efficiency.

### SUMMARY

For this reason, the present invention provides an improved Light-Emitting Diode (LED) package structure, for reducing the power loss and improving the luminous efficiency.

The present invention provides an improved Light-Emitting Diode (LED) package structure of semi-conductor material package substrate such as silicon, or gallium arsenic for improving the thermal conductivity during the operation.

The present invention provides an improved Light-Emitting Diode (LED) package structure with plural thermal vias passing through the conductive stand in the pit of the package substrate, for conducting the circuit and the heat during operation.

The present invention provides an improved Light-Emitting Diode (LED) package structure with the reflecting cap device set up for the specific angle of light beam according to the manufacture specification.

The improved Light-Emitting Diode (LED) package structure of the invention comprises a package substrate of semi-conductor material with a pit, for installing at least an LED chip; a conductive stand, partially exposing in the pit and electrically connecting to the LED chip; and a conducting line, connecting between the conductive stand and the LED chip. By the plural thermal vias passed through the package substrate within the pit area, and the conductive metallic materials filled in the thermal vias, provides conducting the circuit of both sides of the conductive stand, and conducting the heat out of the package structure during LED operation to enhance the thermal conductivity of the whole package structure. The sidewall of the pit comprises a reflective metallic layer or a reflecting cap device clamping the sidewall for a specific angle, rendering the light to radiate out by reflecting or scattering to enhance the luminous efficiency.

According to the preferred embodiment of this invention, the improved Light-Emitting Diode (LED) package structure is applied in the package structure such as the normal Light-Emitting Diode, the high power Light-Emitting Diode, the Laser Diode etc., for reducing the power loss and improving the luminous efficiency during the LED operation.

In conclusion, the improved Light-Emitting Diode (LED) package structure of this invention provides a package structure with the low light power reduction and high luminous efficiency, and with high thermal conductivity. Additional equipment is not necessary for manufacturing the package structure, but only boring plural thermal vias on the package substrate. And depending on the demand of thermal conductivity, it is possible to enhance the thermal conducting efficiency by boring more thermal vias, thus the cost of the material is never added.

### BRIEF DESCRIPTION OF THE DRAWINGS

The invention can be more fully understood by reading the following detailed description of the embodiment, with reference made to the accompanying drawings as follows:

FIG. 1 illustrates the vertical view of the preferred embodiment of the improved Light-Emitting Diode (LED) package structure of this invention.

FIG. 2 illustrates the side perspective drawing of the preferred embodiment of the improved Light-Emitting Diode (LED) package structure of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

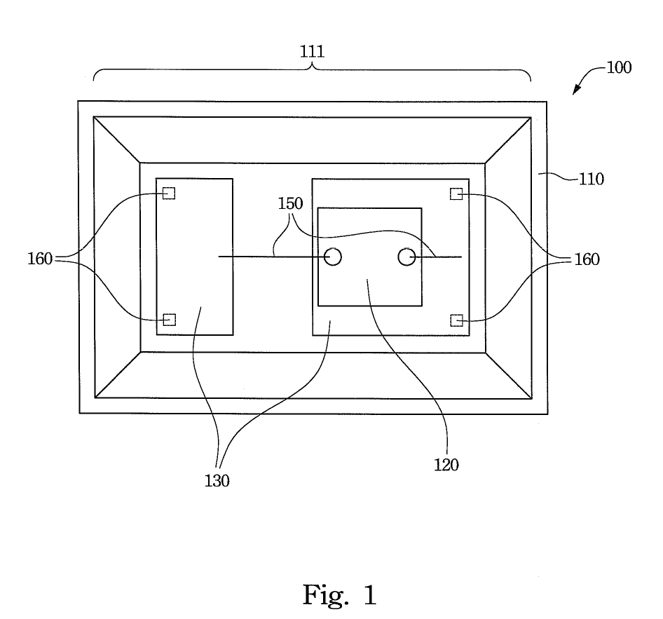

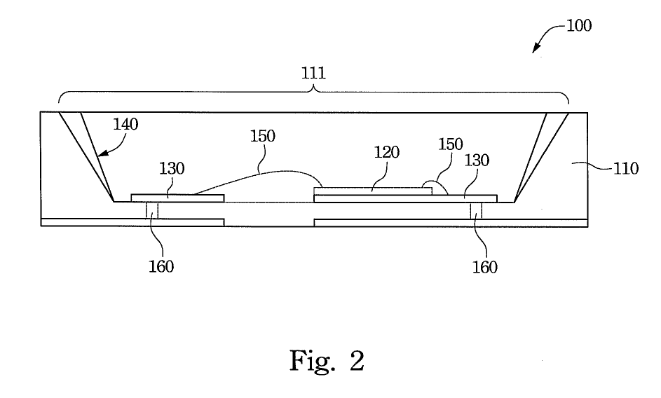

Refer to FIG. 1 and FIG. 2. FIG. 1 is the vertical view of the preferred embodiment of the improved Light-Emitting Diode (LED) package structure of this invention, while FIG. 2 is the side perspective drawing of the preferred embodiment of the improved Light-Emitting Diode (LED) package structure of this invention. The improved LED package structure 100 of this invention comprises a package substrate 110, having a pit 111 thereon for placing at least an LED chip 120. A conductive stand 130 partially exposes in the pit 111 and electrically connects to the LED chip 120 via a conducting line 150, wherein the superficial material of the conductive stand 130 can be of gold, silver, and copper.

Wherein the material of the package substrate 110 comprises the heat conductive material, such as the silicon-containing substrate, and the gallium arsenic package substrate etc. The sidewall around the pit 111 of the package substrate 110 can be covered with a reflective metallic layer, or set up a reflecting cap device 140 in the pit 111, with the reflecting surface of the reflecting cap device 140 clamping the sidewall for a specific angle. Therefore, the light beaming on the sidewall of the pit 111 is able to emit out via reflection and refraction, to improve the luminous efficiency of the LED.

Moreover, a plurality of thermal vias 160 passing through the part of the conductive stand 130 within the pit 111 area, and filled with conductive metallic materials in the thermal vias 160, provides conducting the circuit of both sides of the conductive stand 130. And by means of the superior thermal conductivity of metallic materials, the conductive metallic materials in the thermal vias 160 provide conducting the heat out of the LED package structure 100 due to the LED operation. Also, the efficiency of the heat radiation is improved by adding the amount of the thermal vias 160 depending on the radiation specification.

Therefore, the efficiency of the heat radiation of the whole package structure is able to be improved through the semi-conductor material package substrate of high thermal conductivity, the thermal vias on the conductive stand, and the conductive metallic materials filled in the thermal vias.

The improved Light-Emitting Diode (LED) package structure presented in this invention is applied in the package structure such as the normal Light-Emitting Diode, the high power Light-Emitting Diode, the Laser Diode etc., for reducing the power loss and improving the luminous efficiency during the LED operation.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An improved Light-Emitting Diode (LED) package structure, comprising:
an LED chip;
a silicon-containing package substrate, having a pit for placing the LED chip;
a conductive stand, exposed in the pit and electrically connected to the LED chip; and
a thermal via, passing through the silicon-containing package substrate within the pit area.

2. The package structure as claim 1, wherein the thermal via comprises conductive metallic materials filled within.

3. The package structure as claim 1, wherein the pit comprises a sidewall, having a reflective metallic layer.

4. The package structure as claim 1, wherein the pit comprises a reflecting cap device, having a reflecting surface clamping the sidewall for a specific angle.

5. An improved Light-Emitting Diode (LED) package structure, comprising:
an LED chip;
a gallium arsenic package substrate, having a pit for placing the LED chip;
a conductive stand, exposed in the pit and electrically connected to the LED chip; and
a thermal via, passing through the gallium arsenic package substrate within the pit area.

6. The package structure as claim 5, wherein the thermal via comprises conductive metallic materials filled within.

7. The package structure as claim 5, wherein the pit comprises a sidewall, having a reflective metallic layer.

8. The package structure as claim 5, wherein the pit comprises a reflecting cap device, having a reflecting surface clamping the sidewall for a specific angle.
